(19) United States
(12) Patent Application Publication
(10) Pub. No.: US 2022/0363148 A1
(43) Pub. Date: Nov. 17, 2022

(54) ABNORMALITY DETERMINATION APPARATUS AND INFORMATION PROVIDING APPARATUS

(71) Applicant: TOYOTA JIDOSHA KABUSHIKI KAISHA, Aichi-ken (JP)

(72) Inventors: Toshiya HASHIMOTO, Miyoshi-shi (JP); Daiki YOKOYAMA, Gotemba-shi (JP)

(21) Appl. No.: 17/721,361

(22) Filed: Apr. 15, 2022

(30) Foreign Application Priority Data
May 11, 2021 (JP) 2021-080304

(51) Int. Cl. B60L 53/126; B60L 58/12

(52) U.S. Cl. CPC B60L 53/126; B60L 58/12

(57) ABSTRACT

The processor of the processing unit of the abnormality determination device is configured to calculate a number ratio between (i) a number of mobile units having the power transmission efficiency less than a predetermined value and (ii) a number of mobile units having the power transmission efficiency greater than or equal to the predetermined value for each power reception location, based on the power reception history information of the plurality of mobile units stored in the storage unit, and determine an abnormality of the power transmitting device or the power receiving device of a mobile unit among the plurality of mobile units, based on the number ratio for each power reception location.

### FIELD

The present disclosure relates to an abnormality determination apparatus and an information providing apparatus.

### BACKGROUND OF THE DISCLOSURE

JP2010-167898A discloses a vehicle configured to be able to charge the battery by the Dynamic Wireless Power Transfer.

### SUMMARY

The Dynamic Wireless Power Transfer System has a problem in that, when an abnormality occurs in the power transmission from the power transmitting device to the power receiving device, it is difficult to determine whether the cause of the abnormality is the power transmitting device installed on the road or the power receiving device provided on the vehicle.

The present disclosure has been made in view of such problems. The purpose of the present disclosure is to make it possible to determine whether the cause of the abnormality is in the power transmitting device or in the power receiving device.

In order to solve the above problems, an abnormality determination apparatus includes a processing unit including a processor, a communication unit configured to communicate with a plurality of mobile units each including a power receiving device for receiving electric power wirelessly transmitted from a power transmitting device installed on a road, and a storage unit configured to store power reception history information received from the plurality of mobile units. The power reception history information includes, for each of the plurality of mobile units, a power reception location of the power received by the power receiving device, and the received power, or a power transmission efficiency calculated based on the received power. The processor is configured to calculate a number ratio between (i) a number of mobile units having the power transmission efficiency less than a predetermined value and (ii) a number of mobile units having the power transmission efficiency greater than or equal to the predetermined value for each power reception location, based on the power reception history information of the plurality of mobile units stored in the storage unit, and determine an abnormality of the power transmitting device or the power receiving device of a mobile unit among the plurality of mobile units, based on the number ratio for each power reception location.

Further, in order to solve the above problems, an information providing apparatus is configured to provide information to an occupant of a mobile unit including a power receiving device for receiving electric power wirelessly transmitted from a power transmitting device installed on a road, and provide the occupant with information informing that an abnormality has occurred in the power receiving device.

According to these aspects of the present disclosure, when an abnormality occurs in the power transmission from the power transmitting device to the power receiving device, it is possible to determine whether the cause of the abnormality is in the power transmitting device or in the power receiving device.

### BRIEF DESCRIPTION OF THE DRAWINGS

FIG. 1 is a schematic configuration diagram of a Dynamic Wireless Power Transfer System.

FIG. 2 is a diagram illustrating a detailed configuration of a power transmitting device and a vehicle according to the first embodiment of the present disclosure.

FIG. 3 is a flowchart for explaining the content of processing executed between each vehicle and the server in order to aggregate the power reception history information of each vehicle in the server.

FIG. 4 is a flowchart for explaining the contents of the processing executed in the server 1 and the contents of the processing executed in the vehicle 4 accompanying the processing in order to detect an abnormality in power transmission and determine whether the cause is the power transmitting device or the power reception apparatus.

### DESCRIPTION OF EMBODIMENTS

Hereinafter, embodiments of the present disclosure will be described in detail with reference to the drawings. In the following description, like components are denoted by the same reference numerals.

### First Embodiment

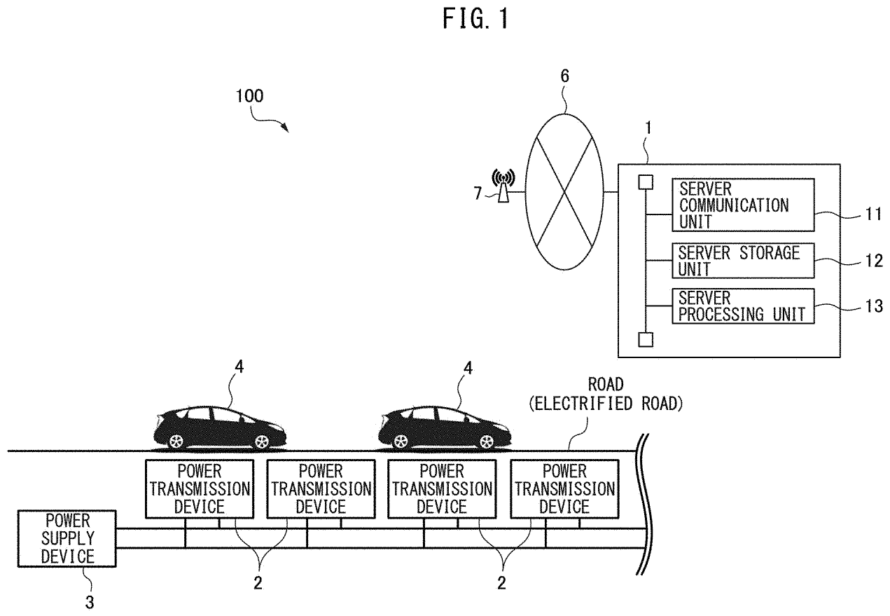

FIG. 1 is a schematic configuration diagram of a Dynamic Wireless Power Transfer System 100 according to a first embodiment of the present disclosure.

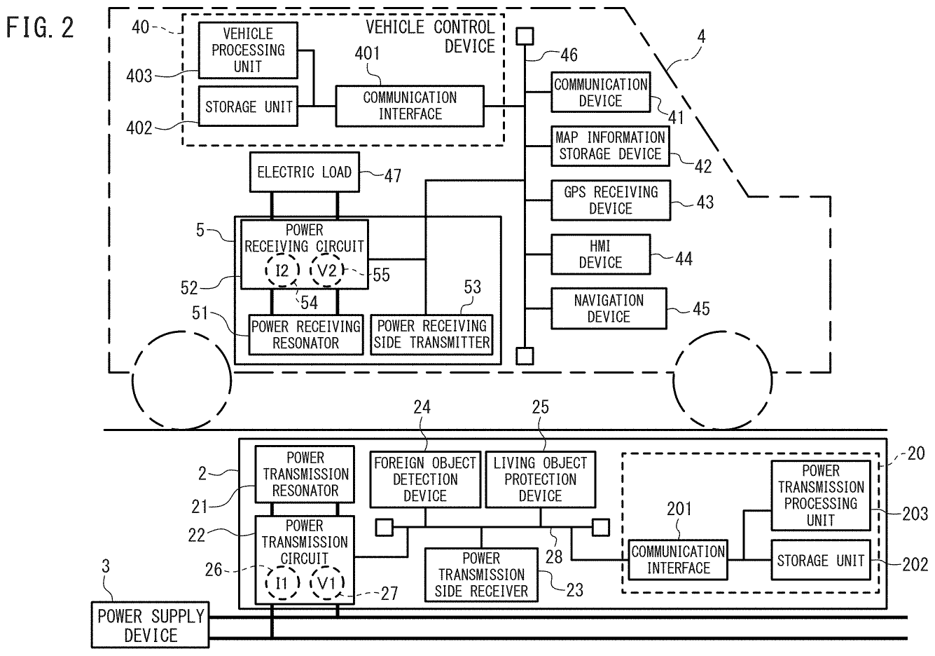

The Dynamic Wireless Power Transfer System 100 according to the present embodiment includes a server 1, a plurality of power transmitting devices 2 which are installed at predetermined intervals along the road, a power supply device 3 for supplying power to each power transmitting device 2, and a plurality of vehicles 4 each having a power receiving device 5 (refer to FIG. 2) for receiving power wirelessly transmitted from the power transmitting devices 2. In the following description, the road where the power transmitting devices 2 are installed is referred to as an “electrified road” if necessary.

The server 1 includes a server communication unit 11, a server storage unit 12, and a server processing unit 13.

The server communication unit 11 has a communication interface circuit for connecting the server 1 to the network 6 via, for example, a gateway. The server communication unit 11 is configured to be able to mutually communicate with the vehicle 4.

The storage unit 12 includes storage media such as HDDs (Hard Disk Drive), optical recording media, and semi-conductor memories. The server storage unit 12 stores various computer programs, data, and the like used for processing in the server processing unit 13.

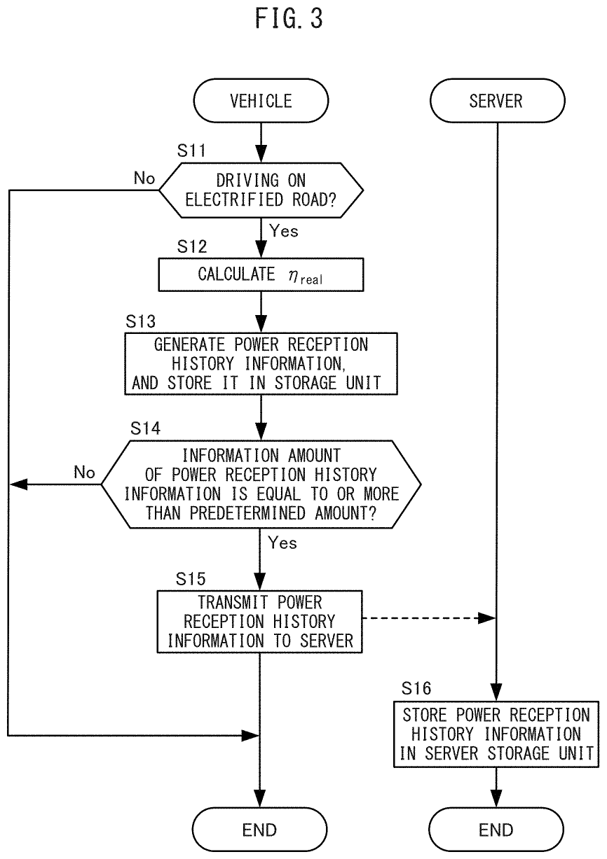

The server processing unit 13 includes one or a plurality of CPUs (Central Processing Unit) and peripheral circuits thereof. The server processing unit 13 executes various computer programs stored in the server storage unit 12, and collectively controls the overall operation of the server 1. The server processing unit 13 is, for example, a processor. The processing performed by the server processing unit 13, and thus the server 1, will be described later with reference to FIGS. 3 to 6.

FIG. 2 is a diagram illustrating a detailed configuration of the power transmitting device 2 and the vehicle 4 according to the present embodiment.

The power transmitting device 2 includes a power transmission resonator 21, a power transmission circuit 22, a power transmission-side receiver 23, a foreign object detection device 24, a living object protection device 25, and a power transmission controller 20. The power transmission circuit 22, the power transmission side receiver 23, the foreign object detection device 24, and the living object protection device 25 are connected to the power transmission controller 20 via an internal network 28 in the power transmitting device 2 conforming to the standard such as CAN (Controller Area Network).

The power transmission resonator 21 is a resonant circuit including a power transmission coil. The power transmission resonator 21 is configured to resonate at a predetermined resonant frequency f₀. In the vehicle 4, a power receiving resonator 51 corresponding to the power transmission resonator 21 is provided. The power receiving resonator 51 is a resonant circuit including a power receiving coil. The power receiving resonator 51 is configured to resonate at the same resonant frequency f₀ as that of the power transmitting resonator 21. By resonating the power receiving coil and the power transmission coil, the power receiving resonator 51 and the power transmission resonator 21 disposed apart in space are magnetically coupled. As a result, power transmission from the power transmitting device 2 to the power receiving device 5 (wireless power transfer) is performed.

The power transmission circuit 22 is an electrical circuit comprising an inverter. The power transmission circuit 22, based on the control signal from the power transmission controller 20, is configured so that the DC power supplied from the power supply device 3 can be converted into a desired AC power supplied to the power transmission resonator 21. The power transmission circuit 22 is provided with a power transmission side current sensor 26 for detecting a current I1 flowing through the power transmission resonator 21. In the power transmission circuit 22, the power transmission side voltage sensor 27 for detecting the voltage V1 applied to the power transmission resonator 21 is provided. Transmission side current I1 detected by the power transmission side current sensor 26 is input to the power transmission controller 20. Transmission side voltage V1 detected by the power transmission side voltage sensor 27 is input to the power transmission controller 20.

The power transmission-side receiver 23, using a predetermined wireless communication link, performs wireless communication with the power receiving-side transmitter 53 mounted on each vehicle 4. The power transmission-side receiver 23 receives the approach signal transmitted from the power receiving-side transmitter 53. The approach signal is a signal for informing that the vehicle 4 is approaching the power transmitting device 2. In other words, the approach signal is a signal for prompting the power transmitting device 2, which has received the approach signal, to prepare for transmission.

The foreign object detection device 24 detects the metal foreign object present on the road between the power transmitting device 2 and the power receiving device 5. This is because when the power transmission from the power transmitting device 2 to the power receiving device 5 is performed in a state where the metal foreign object is present in the space between the power transmitting device 2 and the power receiving device 5, there is a possibility that the power transmission efficiency is lowered, due to the metal foreign object being heated. The foreign object detection device 24, in response to a request from the power transmission controller 20, transmits the foreign object detection information whether the metal foreign object is present to the power transmission controller 20. The method of detecting a metal foreign object by the foreign object detection device 24 is not particularly limited, and various known methods such as detection by a metal detector can be used.

The living object protection device 25 detects a living object, such as a human or an animal, existing in the vicinity of the power transmitting device 2. This is because when the power transmitting device 2 is driven in a state where a living object is present around the power transmitting device 2, the living object is exposed to the leakage magnetic field from the power transmitting device 2, which may affect health. In response to a request from the power transmission control device 20, the living object protection device 25 transmits biometric detection information as to whether or not a living object is present around the power transmission control device 20. A method of detecting a living object by the living object protection device 25 is not particularly limited, and various well known methods such as image recognition can be used, for example.

The power transmission controller 20 includes a communication interface 201, a storage unit 202, and a power transmission processing unit 203.

The communication interface 201 is a communication interface circuit for connecting the power transmission control device 20 to the internal network 28 in the power transmitting device 2.

The storage unit 202 includes a storage medium such as an HDD, an optical recording medium, or a semiconductor memory, and stores various computer programs and data used for processing in the power transmission processing unit 203.

The power transmission processing unit 203 includes one or a plurality of CPUs and peripheral circuits thereof. The power transmission processing unit 203 collectively controls the power transmitting device 2 by executing various computer programs stored in the storage unit 202. The power transmission processing unit 203 is, for example, a processor.

Upon receiving the approach signal via the power transmission side receiver 23, the power transmission processing unit 203, and thus the power transmission control device 20, drives the foreign substance detection device 24 and the biological protection device 25 to acquire foreign substance detection information and biological detection information. When the presence of at least one of a metal foreign substance and a living object is confirmed, the power transmission control device 20 controls the power transmission circuit 22 so that the power transmission from the power transmitting device 2 to the power receiving device 5 is not performed. On the other hand, when the presence of the metallic foreign object and the living object is not confirmed, the power transmission control device 20 controls the power transmission circuit 22 so that the transmission power P1 [W] becomes a predetermined target transmission power P1_{t g t}.

In the present embodiment, the target transmission power P1_{t g t} is set to a predetermined fixed value. However, if the approaching signal includes information about the requested power of the vehicle 4 which is the source of the approaching signal, the target transmission power P1_{t g t} may be set as the requested power.

Note the power transmission side current I1 is correlated with the engagement coefficient k indicating the magnetic engagement degree between the power receiving coil of the power receiving resonator 51 and the power transmission coil of the power transmission resonator 21. The power transmission side current I1 tends to increase as the engagement coefficient k is small. Therefore, after receiving the approach signal, for example, by monitoring the power transmission side current I1, it is possible to determine the approach and departure of the vehicle 4 with respect to the power transmitting device 2. The control of the power transmission circuit 22 can be started or terminated in response to the determination.

The vehicle 4 includes a communication device 41, a map information storage device 42, a GPS receiving device 43, an HMI device 44, a navigation device 45, a power receiving device 5, and a vehicle control device 40. The communication device 41, the map information storage device 42, the GPS receiving device 43, the HMI device 44, the navigation device 45, and the power receiving device 5 are connected to the vehicle control device 40 via an in-vehicle network 46 conforming to a standard such as CAN.

The communication device 41 is an in-vehicle terminal having a wireless communication function. The communication apparatus 41 accesses a wireless base station 7 (see FIG. 1) connected to the network 6 (see FIG. 1) via a gateway or the like, and is thereby connected to the network 6 via the wireless base station 7. As a result, the vehicle 4 and the server 1 communicate with each other.

The map information storage device 42 stores map information including location information of roads, information on road types, for example, information on whether a road is an electrified road, and the like.

The GPS receiving device 43 receives radio waves from an artificial satellite to identify the latitude and longitude of the own vehicle 4, and detects the current position of the own vehicle 4. The GPS receiving device 43 transmits the detected current position of the own vehicle 4 to the vehicle control device 40.

The HMI device 44 is an interface for exchanging information with a vehicle occupant. The HMI device 44 according to the present embodiment includes a display and a speaker for providing various types of information to the vehicle occupant, and a touch panel (or operation buttons) for the vehicle occupant to perform an information input operation. The HMI device 44 transmits the input information input by the vehicle occupant to various devices requiring the input information, for example, a navigation device if the input information is a destination. The HMI device 44 provides information received via the in-vehicle network 46 to a vehicle occupant by displaying the information on a display or the like.

The navigation device 45 is a device for guiding the vehicle 4 to a destination set by the vehicle occupant via the HMI device 44. For example, the navigation device 45 sets a travel route to the destination based on the current position information and the map information of the vehicle 4. Then, the navigation device 45 transmits the information relating to the set travel route as navigation information to the vehicle braking controller 40 and the HMI device 44 or the like.

The power receiving device 5 includes a power receiving resonator 51, a power receiving circuit 52, a power receiving side transmitter 53.

The power receiving resonator 51, as described above, is a resonant circuit including a power receiving coil. The power receiving resonator 51 is configured to resonate at the same resonant frequency fₒ as that of the power transmitting resonator 21.

The power receiving circuit 52 is an electric circuit comprising a rectifier and a DC/DC converter. The power receiving circuit 52 converts, by the rectifier, the AC power output from the power receiving resonator 51 to DC power which is supplied to the electric load 47 via the DC/DC converter. The electric load 47 includes, for example, a battery, an electric motor, and the like, but is not particularly limited thereto. In the present embodiment, the power receiving circuit 52 is connected to a battery as the electric load 47. The power receiving circuit 52 is provided with a power receiving side current sensor 54 for detecting an output current I2 of the rectifier. The power receiving circuit 52 is provided with a power receiving side voltage sensor 55 for detecting an output voltage V2 of the rectifier. Receiving side current I2 detected by the power receiving side current sensor 54 is input to the vehicle control device 40. Receiving side voltage V2 detected by the power receiving side voltage sensor 55 is input to the vehicle control device 40.

The power receiving side transmitter 53 performs wireless communication with the power transmission side receiver 23 of each power transmitting device 2 using a predetermined wireless communication link. The power receiving side transmitter 53 transmits the approach signal described above to each power transmitting device 2.

The vehicle control device 40 includes a communication interface 401, a storage unit 402 and the vehicle processing unit 403.

The communication interface 401 is a communication interface circuit for connecting the vehicle control device 40 to the in-vehicle network 46.

The storage unit 402 includes a storage medium such as an HDD, an optical recording medium, or a semiconductor memory. Storage unit 402 storages various computer programs and data or the like used for processing in the vehicle processing unit 403.

The vehicle processing unit 403 includes one or a plurality of CPUs and peripheral circuits thereof. The vehicle processing unit 403 executes various computer programs stored in the storage unit 402 to integrally control the vehicle 4. The vehicle processing unit 403 is, for example, a processor.

The vehicle processing unit 403, and thus the vehicle control device 40, for example, when detecting that the vehicle 4 is approaching the electrified road, starts transmitting the approach signal via the power receiving side transmitter 53. The vehicle control device 40 controls the power receiving circuit 52 (DC/DC converter) to control the power receiving voltage V2 to the target power receiving voltage V2_{t g t}. This is because the power transmission efficiency η between the resonators is correlated with the power receiving voltage V2. In the present embodiment, the target power receiving voltage V2_{t g t} is set to a predetermined voltage at which a desired power transmission efficiency η_{t g t} can be obtained.

The method of detecting a vehicle approaching an electrified road is not particularly limited. For example, based on the current position information and the navigation information of the vehicle 4 (travel route), it may be detected that the vehicle approaches the electrified road. Further, for example, if the infrastructure equipment installed in front of the electrified road is transmitting a signal to the passing vehicle 4 to inform that it will pass through the electrified road, by receiving the signal, it may be detected that the vehicle is approaching the electrified road.

Incidentally, in the dynamic wireless power transfer system 100, the power transmitting device 2 and the power receiving device 5 are physically separated. Therefore, the dynamic wireless power transfer system 100 has a problem in that, when an abnormality occurs in the power transmission from the power transmitting device 2 to the power receiving device 5, it must be determined whether the cause of the abnormality is in the power transmitting device 2 or in the power receiving device 5.

Therefore, in the present embodiment, the power reception history information of each vehicle 4 is aggregated in the server 1. Then, the abnormality of the power transmission is detected based on the power reception history information of each vehicle 4 collected in the server 1 and is determined whether the cause of the power transmission abnormality occurs in the power transmitting device 2, or the power receiving device 5. In the present embodiment, the power reception history information of the vehicle 4 is information in which the following three pieces of information (1) to (3) are associated with each other.

(1) Information on the actual power transmission efficiency η_{r e a l} calculated based on the received power P2 [W] received by the power receiving device 5 while traveling on the electrified road
(2) Position of the location where the power transfer efficiency η_{r e a l} was obtained (i.e., the location where the received power P2 was received)
(3) Identification information of the own vehicle

Hereinafter, the abnormality detection control of the power transmission according to the present embodiment is described.

FIG. 3 is a flowchart for explaining the content of processing executed between each vehicle 4 and the server 1 in order to aggregate the power reception history information of each vehicle 4 in the server 1.

In step S11, the vehicle control device 40 of each vehicle 4, based on the current position information and the map information of the own vehicle 4, determines whether or not the own vehicle 4 is traveling on the electrified road. The vehicle control device 40 of each vehicle 4, if the vehicle 4 is traveling on the electrified road, proceeds the process to step S12. On the other hand, the vehicle control device 40 of each vehicle 4, if the own vehicle 4 is not traveling on the electrified road, ends the present process.

In step S12, the vehicle control device 40 of each vehicle 4, based on the received current I2 and the received voltage V2, calculates the received power P2 received by the power receiving device 5. Then, the vehicle control device 40 calculates the power transmission efficiency η_{r e a l} (=P2/P1_{t g t}) by dividing the received power P2 by the target transmission power P1_{t g t}.

If the value of the target transmission power P1_{t g t} is a fixed value as in the present embodiment, the value can be acquired by storing the fixed value in the storage unit 402 of the vehicle control device 40 of the vehicle 4. Further, for example, in the vehicle control device 40 of the respective vehicles 4, if the requested power is calculated based on the state of the electric load 47 (e.g., the battery charge rate if the electric load 47 is a battery) and the information relating to the requested power is included in the approach signal, the requested power can be the target transmission power P1_{t g t}.

In step S13, the vehicle control device 40 of each vehicle 4 generates power reception history information in which the power transmission efficiency η_{r e a l}, the location information of the location where the power transmission efficiency η_{r e a l} is obtained, and the identification information of each vehicle are associated with each other, and stores the generated power reception history information in the storage unit 402. In the present embodiment, the position of the vehicle 4, when the power receiving current I2 and the power receiving voltage V2 were used for the calculation of the power transmission efficiency η_{r e a l}, is used as the position of the location (i.e., the power reception location of the received power P2) where the power transmission efficiency η_{r e a l} was obtained.

In step S14, the vehicle control device 40 of each vehicle 4 determines whether or not the information amount of the power reception history information stored in the storage unit 402 is equal to or more than a predetermined amount. The vehicle control device 40 of each vehicle 4, if the information amount of the power reception history information is equal to or greater than the predetermined amount, proceeds the process to step S15. On the other hand, the vehicle control device 40 of each vehicle 4, if the information amount of the power reception history information is less than the predetermined amount, ends the present process.

In step S15, the vehicle control device 40 of each vehicle 4 transmits all the power reception history information stored in the storage unit 402 to the server 1, and deletes the transmitted power reception history information from the storage unit 402.

In step S16, the server 1 stores the power reception history information received from each vehicle 4 in the server storage unit 12. In this manner, the power reception history information of each vehicle 4 is aggregated in the server 1.

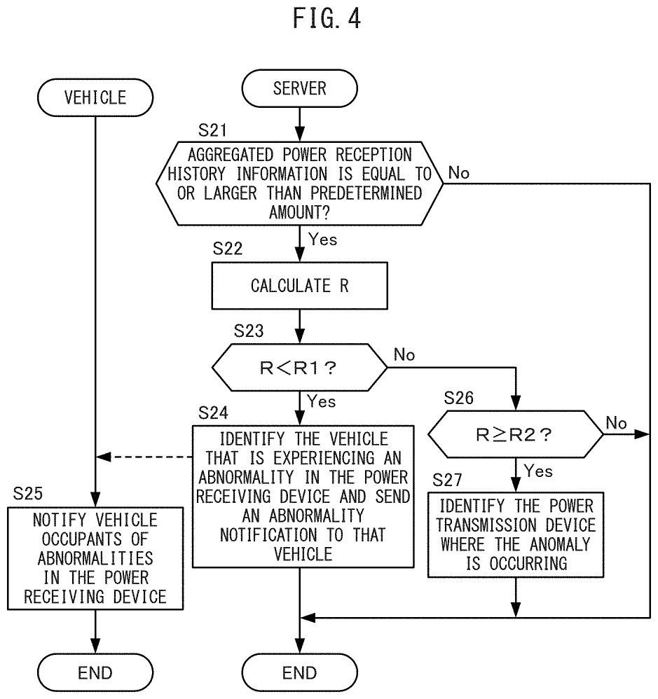

FIG. 4 is a flowchart for explaining the contents of the processing executed in the server 1 and the contents of the accompanying processing executed in the vehicle 4 in order to detect an abnormality in power transmission and determine whether the cause of the occurrence of the abnormality in power transmission is the power transmitting device 2 or the power receiving device 5.

In step S21, the server 1 determines whether or not the information amount of the power reception history information stored in the server storage unit 12, that is, the information amount of the aggregated power reception history information in which the power reception history information of each vehicle 4 is aggregated, is equal to or more than a predetermined amount. If the amount of information in the aggregated power receiving history information is equal to or larger than the predetermined amount, the server 1 proceeds to the process in step S22. On the other hand, if the information amount of the aggregated power reception history information is less than the predetermined amount, the server 1 determines that the information amount for detecting the abnormality of the power transmitting device 2 is not sufficient, and ends the present process.

In step S22, the server 1 refers to the aggregated power reception history information and calculates, for each location where the power transmission efficiency η_{r e a l} is obtained (i.e., for each power reception location), the number NC_{a b n l} of the vehicles 4 in which the power transmission efficiency η_{t g t} is less than the predetermined value η1 (η1<η_{t g t}) and the number NC_{n o r m} of the vehicles 4 in which the power transmission efficiency η_{r e a l} is equal to or greater than the predetermined value η1. Then, the server 1 calculates the ratio of the number NC_{a b n l} and the number NC_{n o r m} (hereinafter referred to as “the number ratio R”). The aggregated power reception history information is, in other words, the power reception history information of the vehicles 4 in which the power transmission efficiency η_{r e a l} and the position information of the location where the power transmission efficiency η_{r e a l} is obtained are associated with each other. The vehicle 4 in which the power transmission efficiency η_{r e a l} is less than the predetermined value η1 is, in other words, a vehicle in which the power transmission may not have been normally performed. The vehicle 4 in which the power transmission efficiency η_{r e a l} is equal to or greater than the predetermined value η1 is, in other words, a vehicle in which power transmission is normally performed.

In the present embodiment, the ratio of the number NC_{a b n l} of vehicles 4 whose power transmission efficiency η_{r e a l} is less than the predetermined value η1 to the number NC_{n o r m} of vehicles 4 whose power transmission efficiency η_{r e a l} is equal to or greater than the predetermined value η1 is defined as the number ratio R, that is, R=NC_{a b n l}/NC_{n o r m} However, the ratio of the number NC_{n o r m} to the number NC_{a b n l} may be set as the number ratio R.

In step S23, the server 1 determines whether there is a location where the number ratio R is less than the predetermined first threshold R1. The location where the number ratio R is less than the first threshold R1 is, in other words, the location where the number NC_{a b n l} of vehicles 4 for which the power transmission is not normally performed is very small with respect to the number NC_{n o r m} of vehicles 4 for which the power transmission is normally performed. Therefore, at that location, rather than the power transmitting device 2, it is considered probable that an abnormality has occurred in the power receiving device 5 of the specific vehicle 4. Then, server 1, if there is a location where the number ratio R is less than the first threshold R1, proceeds the process to step S24. On the other hand, the server 1, if there is no location where the number ratio R is less than the first threshold R1, proceeds the process to step S26.

In step S24, the server 1 refers to the aggregated power reception history information, and specifies the vehicles 4 whose power transmission efficiencies η_{r e a l} are less than the predetermined value η1 at each location where the number ratio R is less than the predetermined first threshold R1. Then, the server 1 transmits an abnormality notification to the specified vehicle 4, for notifying that an abnormality has occurred in the power receiving device 5.

In step S25, the vehicle control device 40 of the vehicle 4, upon receiving the abnormality notification, via the HMI device 44, notifies the vehicle occupant that an abnormality has occurred in the power receiving device 5 of the own vehicle.

In step S26, the server 1 determines whether there is a location where the number ratio R is greater than or equal to a predetermined second threshold R2. The second threshold value R2 is larger than the first threshold value. The location where the number ratio R is equal to or more than the second threshold R2 is, in other words, the location where the number NC_{a b n l} of vehicles 4 for which power transmission is not normally performed is very large with respect to the number NC_{n o r m} of vehicles 4 for which power transmission is normally performed. Therefore, it is probable that there was an abnormality in the power transmitting device 2 at that location. If there is a location where the number ratio R is greater than or equal to the second threshold R2, the server 1 proceeds the process to step S27. On the other hand, if there is no location where the number ratio R is equal to or greater than the second threshold R2, the server 1 ends the current process.

In step S27, the server 1 determines that an abnormality has occurred in the power transmitting device 2 installed at the location where the number ratio R is equal to or greater than the second threshold R2. In this case, the server 1 may inform, to each vehicle 4, the installation location of the power transmitting device 2 where an abnormality has occurred.

The server 1 (abnormality determination device) according to the present embodiment described above includes a server processing unit 13 (processing unit) including a processor, a server communication unit 11 (communication unit) configured to communicate with a plurality of vehicles 4 (mobile units) each including a power receiving device 5 for receiving electric power wirelessly transmitted from a power transmitting device 2 installed on a road, and a server storage unit 12 (storage unit) configured to store power reception history information received from the plurality of vehicles 4. The power reception history information includes, for each of the plurality of vehicles 4, a power reception location of the power received by the power receiving device 5, and the received power, or a power transmission efficiency η_{r e a l} calculated based on the received power. The processor is configured to calculate a number ratio R between (i) a number NC_{a b n l} of vehicles 4 having the power transmission efficiency η_{r e a l} less than a predetermined value η1 and (ii) a number NC_{n o r m} of vehicles 4 having the power transmission efficiency η_{r e a l} greater than or equal to the predetermined value η1 for each power reception location, based on the power reception history information of the plurality of vehicles 4 stored in the server storage unit 12, and determine an abnormality of the power transmitting device 2 or the power receiving device 5 of a vehicle 4 among the plurality of vehicles 4, based on the number ratio R for each power reception location.

In the present embodiment, the number ratio R is a ratio of the number NC_{a b n l} of vehicles 4 having the power transmission efficiency η_{r e a l} less than the predetermined value η1 to the number NC_{n o r m} of vehicles 4 having the power transmission efficiency η_{r e a l} greater than or equal to the predetermined value η1. The processor of the server processing unit 13 is configured to determine that an abnormality has occurred in the power receiving device 5 of the vehicle 4 in which the power transmission efficiency η_{r e a l} is less than the predetermined value η1 at the power reception location in which the number ratio R is less than a predetermined first threshold R1. Further, the processor of the server processing unit 13 is configured to determine that an abnormality has occurred in the power transmitting device 2 installed at the power reception location where the number ratio R is equal to or greater than a predetermined second threshold R2.

As described above, by calculating the number ratio R between the number NC_{a b n l} of vehicles 4 whose power transmission efficiency η_{r e a l} is less than the predetermined value η1 and the number NC_{n o r m} of vehicles 4 whose power transmission efficiency η_{r e a l} is equal to or greater than the predetermined value η1 for each power reception location, the following locations (1) and (2) can be specified.

(1) Location where the number NC_{a b n l} of vehicles 4 for which power transmission was not normally performed is smaller than the number NC_{n o r m} of vehicles 4 for which power transmission was normally performed.
(2) Location where the number NC_{a b n l} of vehicles 4 for which power transmission was not normally performed is larger than the number NC_{n o r m} of vehicles 4 for which power transmission was normally performed.

Then, it is considered that, in a location where the number NC_{a b n l} of vehicles 4 for which power transmission has not been performed normally is small, not the power transmitting device 2 but the power receiving device 5 of a particular vehicle 4 is abnormal. On the other hand, it is considered that an abnormality has occurred in the power transmitting device 2 in a location where NC_{a b n l} of vehicles 4 for which power transmission has not been performed normally is large.

Therefore, according to the present embodiment, when an abnormality occurs in the power transmission from the power transmitting device 2 to the power receiving device 5, it is possible to determine whether the cause of the abnormality is in the power transmitting device 2 or in the power receiving device 5.

Further, the processor of the server processing unit 13 according to the present embodiment is configured to transmit a notification to the vehicle 4, whose power transmission efficiency η_{r e a l} is less than the predetermined value η1 at the power reception location where the number ratio R is less than the first threshold R1, to notify that an abnormality has occurred in the power receiving device 5 of the vehicle 4.

Thus, it is possible to inform that an abnormality has occurred in the power receiving device 5 of the own vehicle to the occupant of the vehicle 4 in which the abnormality has occurred in the power receiving device 5. Therefore, it is possible to prevent the vehicle 4 from being operated with an abnormality in the power receiving device 5, resulting in insufficient charging.

The HMI device 44 (information providing apparatus) according to the present embodiment is configured to provide information to an occupant of a vehicle 4 including a power receiving device 5 for receiving electric power wirelessly transmitted from a power transmitting device 2 installed on a road, and provide the occupant with information informing that an abnormality has occurred in the power receiving device 5.

While embodiments of the present disclosure have been described above, the above embodiment is only a part of the application example of the present disclosure, and the technical scope of the present disclosure is not intended to limit the technical scope of the present disclosure to the specific configuration of the above embodiment.

For example, in the embodiment described above, information in which the power transmission efficiency η_{r e a l} calculated based on the received power P2, the location information of the location where the power transmission efficiency η_{r e a l} is obtained, and the identification information of the own vehicle are associated with each other is transmitted from each vehicle 4 to the server 1 as the received power history information. However, the information associated with the received power P2, the location information of the location where the received power P2 is obtained, and the identification information of the own vehicle, may be transmitted from each vehicle 4 to the server 1 as the power reception history information. Then, in the server 1, the received power may be converted into a power transmission efficiency η_{r e a l}. That is, in the above-described embodiment, the power receiving history information may be information including the received power P2 received by the power receiving device 5 and the power reception location.

In the above embodiment, although the power transmission control device 20 is provided to each power transmitting device 2, a plurality of power transmitting devices 2 may be controlled by one power transmission control device 20. In this case, the control performed by the server 1 in the above embodiment may be performed by the power transmission control device 20.

1. An abnormality determination apparatus, comprising:
a processing unit including a processor;
a communication unit configured to communicate with a plurality of mobile units each including a power receiving device for receiving electric power wirelessly transmitted from a power transmitting device installed on a road; and
a storage unit configured to store power reception history information received from the plurality of mobile units, wherein
the power reception history information includes, for each of the plurality of mobile units:
a power reception location of the power received by the power receiving device, and
the received power, or a power transmission efficiency calculated based on the received power, and
the processor is configured to:
calculate a number ratio between (i) a number of mobile units having the power transmission efficiency less than a predetermined value and (ii) a number of mobile units having the power transmission efficiency greater than or equal to the predetermined value for each power reception location, based on the power reception history information of the plurality of mobile units stored in the storage unit; and
determine an abnormality of the power transmitting device or the power receiving device of a mobile unit among the plurality of mobile units, based on the number ratio for each power reception location.

2. The abnormality determination apparatus according to claim 1, wherein
the processor is configured to determine that an abnormality has occurred in the power receiving device of the mobile unit in which the power transmission efficiency is less than the predetermined value at the power reception location in which the number ratio is less than a predetermined first threshold.

3. The abnormality determination apparatus according to claim 2, wherein
the processor is configured to determine that an abnormality has occurred in the power transmitting device installed at the power reception location where the number ratio is equal to or greater than a predetermined second threshold.

4. The abnormality determination apparatus according to claim 3, wherein
the second threshold is larger than the first threshold.

5. The abnormality determination apparatus according to claim 1, wherein
the number ratio is a ratio of the number of mobile units having the power transmission efficiency less than the predetermined value to the number of mobile units having the power transmission efficiency greater than or equal to the predetermined value.

6. The abnormality determination apparatus according to claim 2, wherein
the processor is configured to transmit a notification to the mobile unit, whose power transmission efficiency is less than the predetermined value at the power reception location where the number ratio is less than the first threshold, to notify that an abnormality has occurred in the power receiving device of the mobile unit.

7. An information providing apparatus configured to provide information to an occupant of a mobile unit including a power receiving device for receiving electric power wirelessly transmitted from a power transmitting device installed on a road, wherein
the information providing apparatus is configured to provide the occupant with information informing that an abnormality has occurred in the power receiving device.
